(19) United States
(12) Patent Application Publication
(10) Pub. No.: US 2025/0174596 A1
(43) Pub. Date: May 29, 2025

(54) METHOD OF MANUFACTURING SEMICONDUCTOR PACKAGE AND APPARATUS FOR MANUFACTURING SEMICONDUCTOR PACKAGE USED THEREFOR

(71) Applicant: SAMSUNG ELECTRONICS CO., LTD., SUWON-SI (KR)

(72) Inventors: Sunchul KIM, Suwon-si (KR); Donguk Aditya kumar KWON, Suwon-si (KR); Gongmyeong KIM, Suwon-si (KR); Chaein MOON, Suwon-si (KR); Hyeonrae CHO, Suwon-si (KR)

(21) Appl. No.: 18/812,158

(22) Filed: Aug. 22, 2024

(30) Foreign Application Priority Data
Nov. 28, 2023 (KR) 10-2023-0168238

(51) Int. Cl. H01L 23/00

(52) U.S. Cl. CPC H01L 24/81; H01L 24/75; H01L 2224/75264; H01L 2224/75744; H01L 2224/81097; H01L 2224/81201; H01L 2224/81238

(57) ABSTRACT

A method of manufacturing a semiconductor package include providing a substrate on a support plate. A semiconductor chip is placed on the substrate by a pick-up tool. An alternating current voltage is supplied to an induction coil positioned adjacent to the semiconductor chip. The pick-up tool includes an insulating material.

### CROSS-REFERENCE TO RELATED APPLICATION

This application claims priority under 35 U.S.C. § 119 to Korean Patent Application No. 10-2023-0168238, filed on Nov. 28, 2023 in the Korean Intellectual Property Office, the disclosure of which is incorporated by reference in its entirety herein.

### TECHNICAL FIELD

The present inventive concept relates to a semiconductor package, and more particularly, to a semiconductor package including a conductive solder.

### DISCUSSION OF RELATED ART

Over the last few decades, discoveries in technology, materials, and manufacturing processes have led to rapid advances in computing power and wireless communication technology. Accordingly, a high integration level for high-performance transistors has been achieved, and the speed of integration has doubled about every 18 months according to Moore's law. The semiconductor manufacturing industry has made transistors increasingly light, thin, short, compact, and power-efficient. Three-dimensional (3D) integrated packaging has been suggested as an effective solution to provide high-performance transistors considering economic and physical process limitations.

The development of 3D integrated apparatuses began with a complementary metal-oxide-semiconductor (CMOS) integrated device suggested in 1980 and has developed through continuous research and development. Examples of 3D integration technology include integration of a logic circuit and a memory circuit, sensor packaging, and heterogeneous integration of a micro-electro-mechanical system (MEMS) and a CMOS. 3D integration technology enables reduction of form factor as well as achievement of high reliability, low power consumption, and low manufacturing costs.

### SUMMARY

Embodiments of the present inventive concept provide a method of manufacturing a semiconductor package having increased performance and reliability.

The objectives of embodiments of the present inventive concept are not limited to those mentioned above, and other objectives that are not mentioned will be clearly understood by those skilled in the art from the following descriptions.

According to an embodiment of the present inventive concept, a method of manufacturing a semiconductor package include providing a substrate on a support plate. A semiconductor chip is placed on the substrate by a pick-up tool. An alternating current voltage is supplied to an induction coil positioned adjacent to the semiconductor chip. The pick-up tool includes an insulating material.

According to an embodiment of the present inventive concept, a method of manufacturing a semiconductor package includes providing a substrate on a support plate. A semiconductor chip and a conductive solder disposed under the semiconductor chip is placed on the substrate by a pick-up tool. An alternating current voltage is supplied to an induction coil positioned adjacent to the conductive solder. Heat is applied to the conductive solder by the alternating current voltage of the induction coil.

According to an embodiment of the present inventive concept, an apparatus for manufacturing a semiconductor package includes a support plate supporting a substrate. A pick-up tool places a semiconductor chip on the substrate. The semiconductor chip includes a conductive solder disposed under the semiconductor chip and positioned between the semiconductor chip and the substrate. An induction coil is positioned adjacent to the semiconductor chip. An alternating current supply supplies an alternating current voltage to the induction coil. When the alternating current voltage is supplied to the induction coil, heat is applied to the conductive solder to bond the substrate and the semiconductor chip together.

### BRIEF DESCRIPTION OF THE DRAWINGS

Embodiments of the present inventive concept will be more clearly understood from the following detailed description taken in conjunction with the accompanying drawings in which:

FIGS. 1 to 3 are flowcharts illustrating a method of manufacturing a semiconductor package, according to embodiments of the present inventive concept;

FIGS. 4 to 9 are cross-sectional views illustrating a method of manufacturing a semiconductor package, according to embodiments of the present inventive concept; and

FIGS. 10 to 16 are cross-sectional views and plan views illustrating an apparatus for manufacturing a semiconductor package, which is used for a method of manufacturing a semiconductor package, according to embodiments of the present inventive concept.

### DETAILED DESCRIPTION OF EMBODIMENTS

Hereinafter, embodiments of the present inventive concept will be described in detail with reference to the accompanying drawings. Like components are denoted by like reference numerals in the drawings, and redundant descriptions thereof are omitted. In the following drawings, a thickness or size of each layer may be exaggerated for convenience and clarity of description, and thus may differ from an actual shape or ratio.

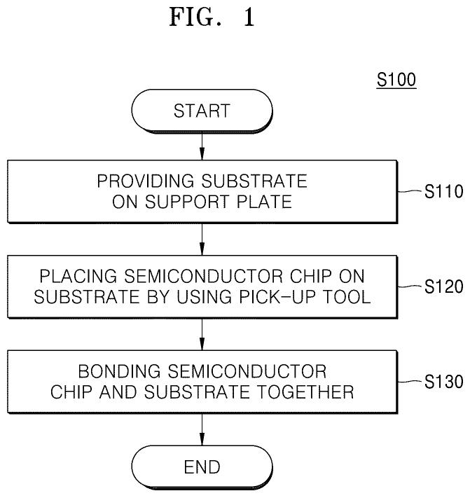

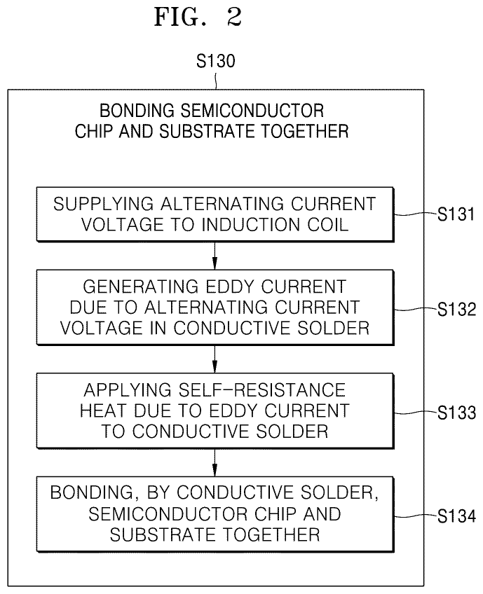

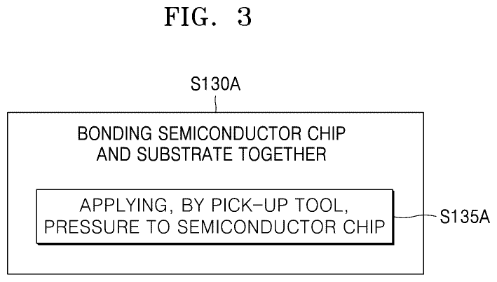

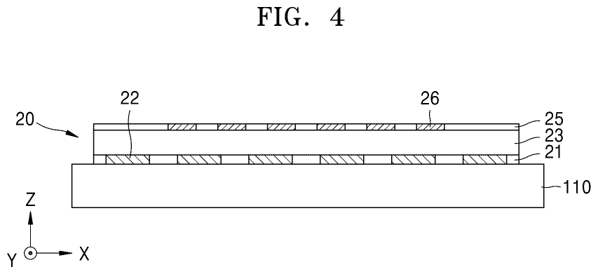

FIGS. 1 to 3 are flowcharts illustrating a method S100 of manufacturing a semiconductor package, according to an embodiment of the present inventive concept. In detail, FIGS. 2 and 3 are flowcharts illustrating some operations of the method S100 of manufacturing a semiconductor package. FIGS. 4 to 9 are cross-sectional views illustrating the method S100 of manufacturing a semiconductor package, according to embodiments of the present inventive concept.

Referring to FIGS. 1 and 4 together, operation S110 of providing a substrate on a support plate may be performed.

As illustrated in FIG. 4, a support plate 110 may support a substrate 20. In some embodiments, the support plate 110 may adsorb and fix the substrate 20. For example, the support plate 110 may adsorb and fix the substrate 20 so that the substrate 20 does not move while the method S100 of manufacturing a semiconductor package is being performed.

In some embodiments, the support plate 110 may adsorb and fix the substrate 20 by using a vacuum device. For example, the support plate 110 may adsorb the substrate 20 to the support plate 110 by applying negative pressure between the support plate 110 and the substrate 20.

In some embodiments, the substrate 20 may include a lower insulating layer 21, a wiring layer 23, and an upper insulating layer 25 that are consecutively stacked in the Z direction.

In some embodiments, the wiring layer 23 may include silicon (Si). Alternatively, the wiring layer 23 may include a semiconductor element, such as germanium (Ge), or a compound semiconductor, such as silicon carbide (SiC), gallium arsenide (GaAs), indium arsenide (InAs), and indium phosphide (InP). Alternatively, the wiring layer 23 may have a silicon on insulator (SOI) structure. For example, in an embodiment the wiring layer 23 may include a buried oxide (BOX) layer. The wiring layer 23 may include a conductive region, for example, an impurity-doped well or an impurity-doped structure. Also, the wiring layer 23 may have various device isolation structures such as a shallow trench isolation (STI) structure.

In some embodiments, the wiring layer 23 may include a plurality of individual devices of various types and an interlayer insulating layer. In an embodiment, the plurality of individual devices may include various microelectronic devices, for example, a metal-oxide-semiconductor field-effect transistor (MOSFET), such as a complementary metal-oxide-semiconductor (CMOS) transistor, an image sensor, such as system large-scale integration (LSI), flash memory, dynamic random-access memory (RAM) (DRAM), static RAM (SRAM), electrically erasable programmable read-only memory (EEPROM), phase-change RAM (PRAM), magnetoresistive RAM (MRAM), resistive RAM (RRAM), or a CMOS imaging sensor (CIS), a micro-electro-mechanical system (MEMS), an active device, and a passive device. In an embodiment, the plurality of individual devices may be formed in the wiring layer 23 in a cell region, and the plurality of individual devices may be electrically connected to the conductive region of the wiring layer 23. The wiring layer 23 may further include a conductive wiring or a conductive plug electrically connecting at least two of the plurality of individual devices to each other or the plurality of individual devices to the conductive region of the wiring layer 23. Also, in an embodiment the plurality of individual devices may be electrically separated from other adjacent individual devices by insulating layers, respectively.

In some embodiments, the wiring layer 23 may be formed to include a plurality of wiring structures for connecting the plurality of individual devices to other wirings formed in the wiring layer 23. In an embodiment, the plurality of wiring structures may include a metal wiring pattern extending in a horizontal direction (e.g., the X direction and/or the Y direction) and a via plug extending in a vertical direction (e.g., the Z direction). In an embodiment, the metal wiring pattern and the via plug may include a barrier layer and a conductive layer. In an embodiment, the barrier layer for the metal wiring pattern and the via plug may include at least one material selected from titanium (Ti), titanium nitride (TiN), tantalum (Ta), and tantalum nitride (TaN). The conductive layer for the metal wiring pattern and the via plug may include at least one metal selected from tungsten (W), aluminum (Al), and copper (Cu). In an embodiment, the plurality of wiring structures may have a multi-layer structure in which two or more metal wiring patterns and two or more via plugs are alternately stacked (e.g., in the Z direction).

In some embodiments, the wiring layer 23 may have lower and upper surfaces that face each other (e.g., in the Z direction). The lower insulating layer 21 may be arranged on (e.g., disposed directly thereon) the lower surface of the wiring layer 23, and the upper insulating layer 25 may be arranged on (e.g., disposed directly thereon) the upper surface of the wiring layer 23. Herein, lower and upper surfaces of a substrate may refer to surfaces that extend in a horizontal direction that is perpendicular to a direction in which the substrate is stacked (e.g., a Z direction). For example, the lower surface may refer to a surface at a low vertical level (e.g., in the Z direction), and the upper surface may refer to a surface at a high vertical level (e.g., in the Z direction). The lower insulating layer 21 and the upper insulating layer 25 may be protective layers for protecting the wiring layer 23 and the wiring structures formed in the wiring layer 23 from external impact or moisture. In some embodiments, the lower insulating layer 21 and the upper insulating layer 25 may include at least one of silicon nitride, silicon oxide, and silicon oxynitride.

In some embodiments, a lower pad 22 may be arranged on (e.g., disposed directly thereon) the lower surface of the wiring layer 23. A side surface of the lower pad 22 may be covered by the lower insulating layer 21. In an embodiment, one surface of the lower pad 22, such as a lower surface (e.g. in the Z direction), may be coplanar with a lower surface of the lower insulating layer 21 and may be exposed to the outside.

In some embodiments, an upper pad 26 may be arranged on (e.g., disposed directly thereon in the Z direction) the upper surface of the wiring layer 23. A side surface of the upper pad 26 may be covered by the upper insulating layer 25. One surface of the upper pad 26, such as an upper surface (e.g., in the Z direction), may be coplanar with an upper surface of the upper insulating layer 25 and may be exposed to the outside. In an embodiment, a conductive solder 35 may be arranged on the upper pad 26 to electrically connect the substrate 20 to a semiconductor chip 30.

According to some embodiments, the lower pad 22 and the upper pad 26 may also include at least one metal selected from tungsten (W), aluminum (Al), and copper (Cu).

Referring to FIGS. 1, 5, and 6 together, operation S120 of placing a semiconductor chip on the substrate by using a pick-up tool may be performed.

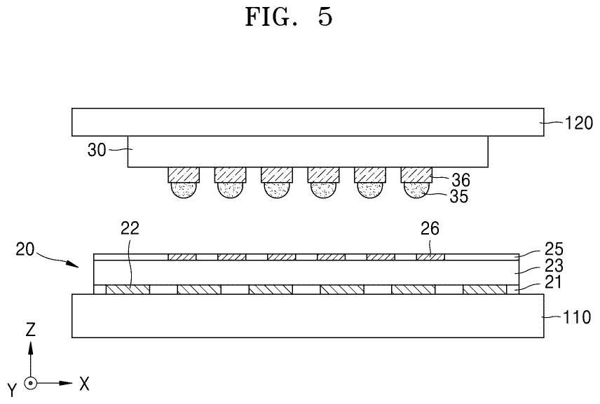

As illustrated in FIG. 5, in an embodiment a pick-up tool 120 may pick up the semiconductor chip 30 and place the semiconductor chip 30 on the substrate 20. The conductive solder 35 may be attached to a lower surface of the semiconductor chip 30. In some embodiments, a bump 36 and the conductive solder 35 may be attached to the lower surface of the semiconductor chip 30. The conductive solder 35 may be placed on (e.g., disposed directly thereon) the substrate 20 by the pick-up tool 120. For example, in an embodiment, the conductive solder 35 may be placed on the substrate 20 by the pick-up tool 120 to directly contact the upper pad 26.

In some embodiments, the semiconductor chip 30 may be, for example, a memory semiconductor chip. The memory semiconductor chip may be, for example, a volatile memory semiconductor chip, such as DRAM or SRAM, or a non-volatile memory semiconductor chip, such as PRAM, MRAM, ferroelectric RAM (FeRAM), or RRAM.

In some embodiments, the semiconductor chip 30 may include silicon (Si). Alternatively, the semiconductor chip 30 may include a semiconductor element, such as germanium (Ge), or a compound semiconductor, such as silicon carbide (SiC), gallium arsenide (GaAs), indium arsenide (InAs), and indium phosphide (InP). The semiconductor chip 30 may have an SOI structure. Also, the semiconductor chip 30 may have various device isolation structures such as an STI structure.

In some embodiments, the pick-up tool 120 may not include a heater. For example, the pick-up tool 120 may not include a heater for heating the semiconductor chip 30. In some embodiments, the pick-up tool 120 may not be heated by a separate heater (e.g., an external heater). For example, the pick-up tool 120 may not be heated by a separate heater and heat the semiconductor chip 30.

In some embodiments, the pick-up tool 120 may include an insulating material. For example, the pick-up tool 120 may be made of (e.g., composed of) an insulating material. For example, the pick-up tool 120 may include a material having low thermal conductivity. For example, the pick-up tool 120 may be made of a material having low thermal conductivity. For example, in an embodiment the pick-up tool 120 may be made of a material such as rubber or ceramic. However, embodiments of the present inventive concept are not necessarily limited thereto.

For example, the pick-up tool 120 may be made of a material that is not easily heated or has low thermal conductivity, and thus, a phenomenon in which the pick-up tool 120 is heated and the semiconductor chip 30 is also heated may be prevented.

In some embodiments, the conductive solder 35 may include a solder material. In an embodiment, the conductive solder 35 may include tin (Sn), indium (In), bismuth (Bi), antimony (Sb), copper (Cu), silver (Ag), zinc (Zn), lead (Pb), and/or an alloy thereof. For example, the conductive solder 35 may include Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, etc. However, embodiments of the present inventive concept are not necessarily limited thereto.

In some embodiments, the bump 36 may be further arranged between the semiconductor chip 30 and the conductive solder 35 (e.g., in the Z direction). The bump 36, together with the conductive solder 35, may mediate an electrical connection between the semiconductor chip 30 and the substrate 20. The bump 36, together with the conductive solder 35, may form a conductive post. In an embodiment, the bump 36 may include at least one metal selected from tungsten (W), aluminum (Al), and copper (Cu). However, embodiments of the present inventive concept are not necessarily limited thereto.

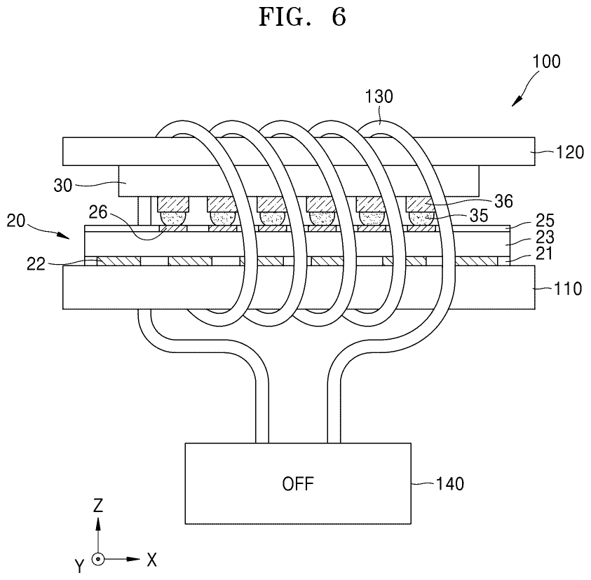

As illustrated in FIG. 6, the semiconductor chip 30 may be arranged on the substrate 20. For example, the conductive solder 35 on the lower surface of the semiconductor chip 30 may be arranged on (e.g., disposed directly thereon) the substrate 20. In an embodiment, the conductive solder 35 may be in direct contact with an upper surface of the substrate 20 or may be arranged adjacent to the upper surface of the substrate 20.

In an embodiment, an induction coil 130 may then be provided adjacent to the conductive solder 35. In some embodiments, an alternating current (AC) supply 140 may be provided to supply an AC voltage to the induction coil 130.

In some embodiments, the pick-up tool 120 may apply pressure to the semiconductor chip 30 to bond the semiconductor chip 30 to the substrate 20. For example, the pick-up tool 120 may apply pressure to the semiconductor chip 30 in a direction towards the substrate 20 (e.g., in a −Z direction). For example, the pick-up tool 120 may apply compression pressure to the semiconductor chip 30.

In some embodiments, when the pick-up tool 120 applies pressure to the semiconductor chip 30, the pressure may be transferred to the conductive solder 35 to bond the semiconductor chip 30 to the substrate 20.

In some embodiments, the conductive solder 35 may be arranged between the semiconductor chip 30 and the substrate 20 (e.g., in the Z direction) to bond the semiconductor chip 30 and the substrate 20 together.

Referring to FIGS. 1, 7, and 8 together, operation S130 of bonding the semiconductor chip and the substrate together may be performed.

In an embodiment, referring to FIG. 2, operation S130 of bonding the semiconductor chip and the substrate together may include operation S131 of supplying an AC voltage to an induction coil, operation S132 of generating an eddy current due to the AC voltage in a conductive solder, operation S133 of applying self-resistance heat due to the eddy current to the conductive solder, and operation S134 of bonding, by the conductive solder, the semiconductor chip and the substrate together.

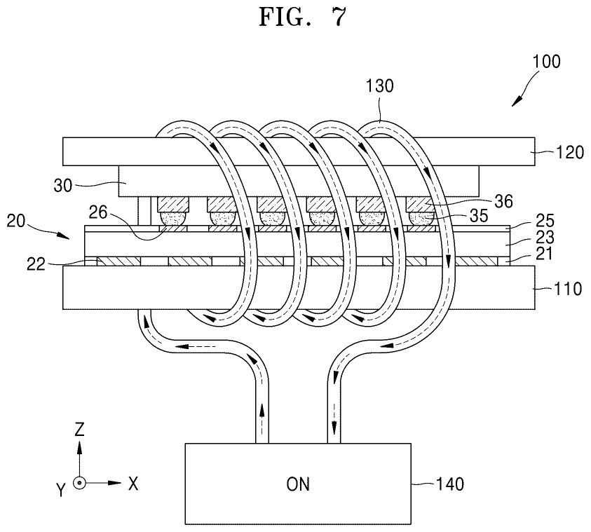

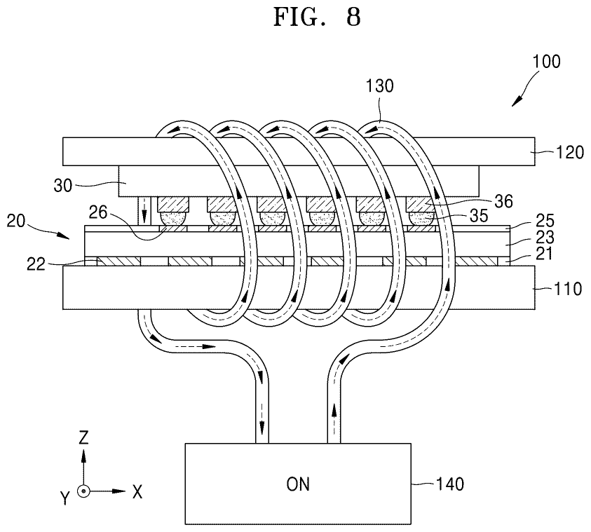

As illustrated in FIGS. 7 and 8, the AC supply 140 may supply an AC voltage to the induction coil 130. When the AC voltage is supplied to the induction coil 130, an electromagnetic field may be formed in a surrounding space, and an eddy current may be generated in the conductive solder 35 adjacent to the induction coil 130 due to an electromagnetic induction phenomenon. As a result, self-resistance heat of the conductive solder 35 may be generated. Due to the self-resistance heat, the conductive solder 35 may be bonded to the substrate 20.

For example, heat may be applied to the conductive solder 35, and the conductive solder 35 may be bonded to the substrate 20 due to the heat. The semiconductor chip 30 may be bonded to the substrate 20 due to the heat applied to the conductive solder 35.

In some embodiments, as described above, the heat applied to the conductive solder 35 may be self-resistance heat of the conductive solder 35 due to the electromagnetic induction phenomenon. For example, since the heat applied to the conductive solder 35 is not heat applied by an external heater but resistance heat of the conductive solder 35 itself, local heating may be performed only on the conductive solder 35 and a local area adjacent thereto.

Referring to FIG. 3, operation S130A of bonding the semiconductor chip and the substrate together may include operation S135A of applying pressure to the semiconductor chip by the pick-up tool. In some embodiments, the pick-up tool 120 may apply compression pressure to the semiconductor chip 30. The semiconductor chip 30 may be bonded to the substrate 20 by the resistance heat of the conductive solder 35 and the compression pressure of the pick-up tool 120.

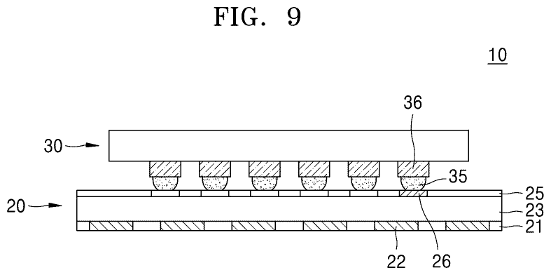

Referring to FIG. 9, a semiconductor package 10 may be manufactured. The semiconductor package 10 may include the substrate 20 and the semiconductor chip 30. The substrate 20 and the semiconductor chip 30 may be bonded together by the conductive solder 35.

According to some embodiments, the method S100 of manufacturing a semiconductor package, in which AC power is applied to the induction coil 130 to induce an eddy current in the conductive solder 35, and due to self-resistance heat of the conductive solder 35 caused by the eddy current, the semiconductor chip 30 and the substrate 20 are bonded together, may be provided.

In contrast, in the case of a comparative example in which heat is applied to the conductive solder 35 by an external heater, rather than using resistance heat of the conductive solder 35 itself, heat may also be applied to the semiconductor chip 30, resulting in performance degradation of the semiconductor chip 30. In the case of a comparative example in which the pick-up tool 120 is provided with a heater to conduct heat to the conductive solder 35 through the semiconductor chip 30, heat may also be applied to the semiconductor chip 30, resulting in performance degradation of the semiconductor chip 30.

For example, according to some embodiments, the method S100 of manufacturing a semiconductor package, by which performance degradation of the semiconductor chip 30 may be reduced or prevented, may be provided. For example, according to some embodiments, the method S100 of manufacturing a semiconductor package having increased performance and reliability may be provided.

Also, time and costs required to entirely heat and cool the semiconductor package 10 may be reduced. For example, according to some embodiments, the method S100 of manufacturing a semiconductor package having increased productivity may be provided.

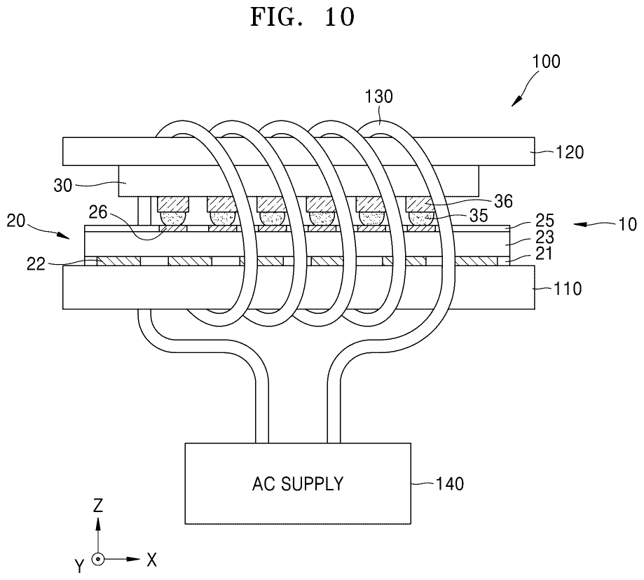

FIGS. 10 to 16 are cross-sectional views and plan views illustrating apparatuses 100 to 105 for manufacturing a semiconductor package, which are used for the method S100 (see FIG. 1) of manufacturing a semiconductor package, according to embodiments of the present inventive concept. The semiconductor package 10 may be manufactured by using the apparatuses 100 to 105 for manufacturing a semiconductor package.

Referring to FIG. 10, the apparatus 100 for manufacturing a semiconductor package may include the support plate 110 for supporting the substrate 20, the pick-up tool 120 for placing the semiconductor chip 30 on the substrate 20, the induction coil 130, and the AC supply 140 for supplying an AC voltage to the induction coil 130.

In some embodiments, the induction coil 130 may be provided adjacent to the conductive solder 35. For example, in an embodiment the induction coil 130 may be provided to surround the conductive solder 35 in a vertical direction (e.g., a Z direction). For example, the induction coil 130 may be provided to surround the support plate 110, the substrate 20, the semiconductor chip 30, the conductive solder 35, and the pick-up tool 120 in the vertical direction (e.g., the Z direction).

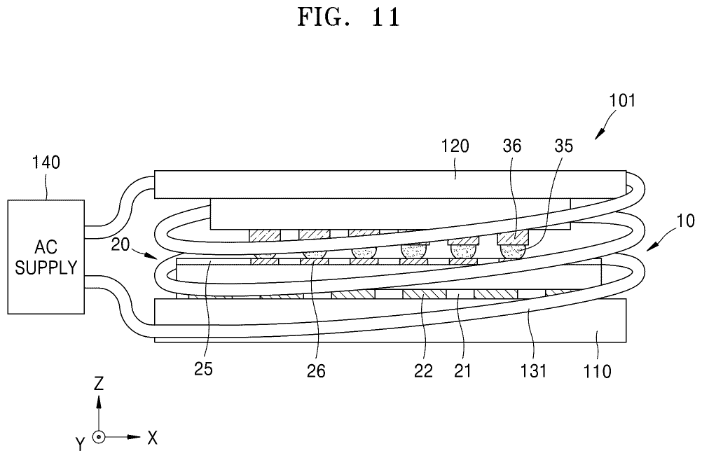

Referring to FIG. 11, the apparatus 101 for manufacturing a semiconductor package may include the support plate 110 for supporting the substrate 20, the pick-up tool 120 for placing the semiconductor chip 30 on the substrate 20, an induction coil 131, and the AC supply 140 for suppling an AC voltage to the induction coil 131.

In some embodiments, the induction coil 131 may be provided adjacent to the conductive solder 35. For example, in an embodiment, the induction coil 131 may surround the conductive solder 35 in a horizontal direction (e.g., the X direction and/or the Y direction). For example, the induction coil 131 may surround the support plate 110, the substrate 20, the semiconductor chip 30, the conductive solder 35, and the pick-up tool 120 in the horizontal direction (e.g., the X direction and/or the Y direction).

As described with reference to FIGS. 1 to 9, the AC supply 140 may supply AC power to the induction coil 131. As a result, self-resistance heat may be generated in the conductive solder 35. Due to the heat, the conductive solder 35 may be bonded to the substrate 20. Due to the heat, the semiconductor chip 30 may be bonded to the substrate 20.

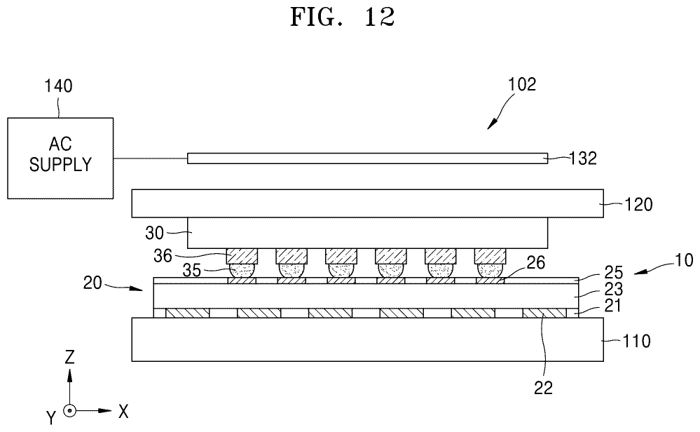

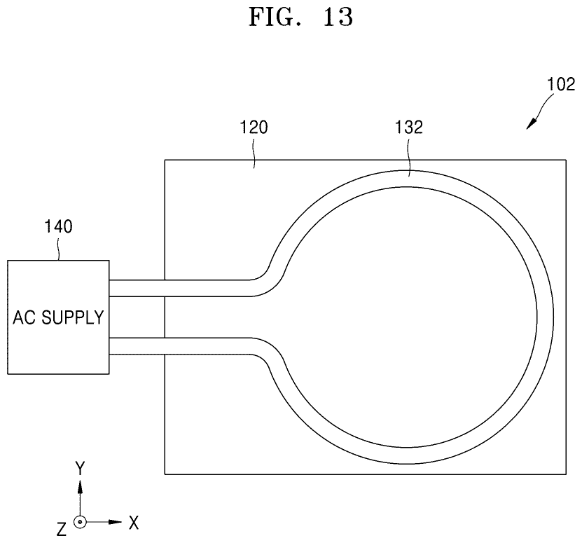

Referring to FIGS. 12 and 13, the apparatus 102 for manufacturing a semiconductor package may include an upper induction coil 132 arranged on the semiconductor chip 30. For example, the upper induction coil 132 may be arranged on the pick-up tool 120. For example, in an embodiment the upper induction coil 132 may overlap the semiconductor chip 30 in the vertical direction (e.g., the Z direction). The upper induction coil 132 may overlap the pick-up tool 120 in the vertical direction (e.g., the Z direction).

As described with reference to FIGS. 1 to 9, the AC supply 140 may supply AC power to the upper induction coil 132. As a result, self-resistance heat may be generated in the conductive solder 35. Due to the self-resistance heat, the conductive solder 35 may be bonded to the substrate 20. Due to the self-resistance heat, the semiconductor chip 30 may be bonded to the substrate 20.

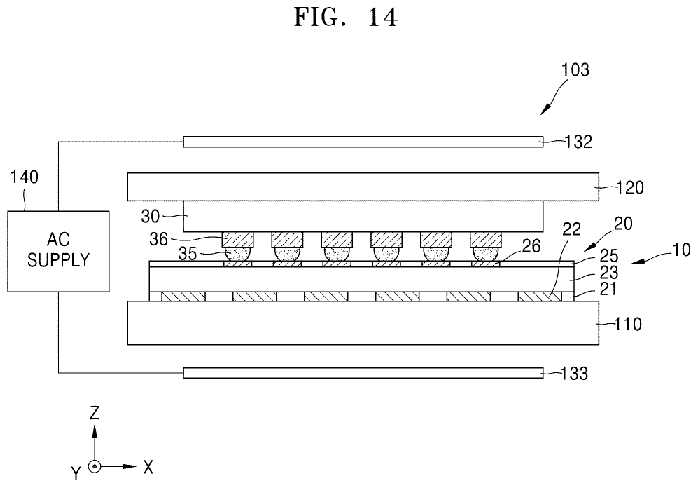

Referring to FIG. 14, in an embodiment the apparatus 103 for manufacturing a semiconductor package may further include a lower induction coil 133 arranged under the semiconductor chip 30. For example, the lower induction coil 133 may be arranged under the support plate 110. The lower induction coil 133 may overlap the semiconductor chip 30 and the support plate 110 in the vertical direction (e.g., in the −Z direction). For example, the lower induction coil 133 may be spaced apart from the upper induction coil 132 with the semiconductor chip 30 therebetween (e.g., in the Z direction). The lower induction coil 133 may be spaced apart from the upper induction coil 132 with the support plate 110, the substrate 20, the semiconductor chip 30, and the pick-up tool 120 therebetween (e.g., in the Z direction).

As described with reference to FIGS. 1 to 9, the AC supply 140 may supply AC power to the upper induction coil 132 and the lower induction coil 133. As a result, self-resistance heat may be generated in the conductive solder 35. Due to the self-resistance heat, the conductive solder 35 may be bonded to the substrate 20. Due to the self-resistance heat, the semiconductor chip 30 may be bonded to the substrate 20.

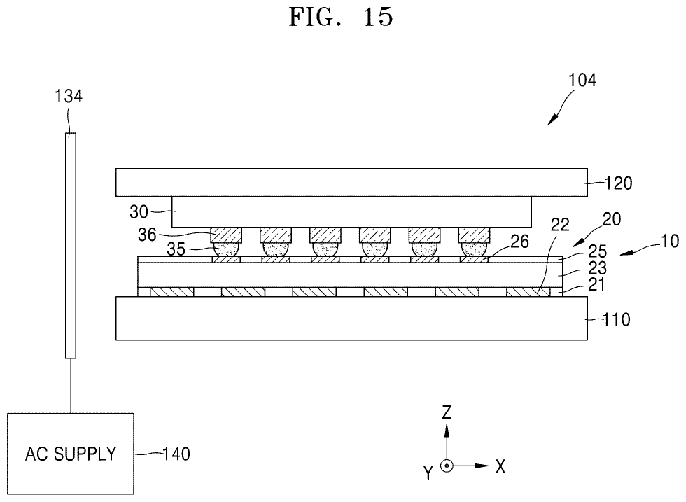

Referring to FIG. 15, the apparatus 104 for manufacturing a semiconductor package may include a first side induction coil 134 arranged on a side of the semiconductor chip 30. For example, in an embodiment, the first side induction coil 134 may be arranged on a lateral side of the semiconductor chip 30 in the −X direction. However, embodiments of the present inventive concept are not necessarily limited thereto. The first side induction coil 134 may be arranged on sides (e.g., a lateral end) of the support plate 110, the substrate 20, the semiconductor chip 30, and the pick-up tool 120. For example, in an embodiment, the first side induction coil 134 may overlap the semiconductor chip 30 in a first horizontal direction (e.g., the X direction). In some embodiments, the first side induction coil 134 may overlap the support plate 110, the substrate 20, the semiconductor chip 30, and/or the pick-up tool 120 in the first horizontal direction (e.g., the X direction).

In some embodiments, the first side induction coil 134 may overlap the semiconductor chip 30 in a second horizontal direction (e.g., the Y direction or a −Y direction). The first side induction coil 134 may overlap the support plate 110, the substrate 20, the semiconductor chip 30, and/or the pick-up tool 120 in the second horizontal direction (e.g., the Y direction or the −Y direction).

As described with reference to FIGS. 1 to 9, the AC supply 140 may supply AC power to the first side induction coil 134. As a result, self-resistance heat may be generated in the conductive solder 35. Due to the self-resistance heat, the conductive solder 35 may be bonded to the substrate 20. Due to the self-resistance heat, the semiconductor chip 30 may be bonded to the substrate 20.

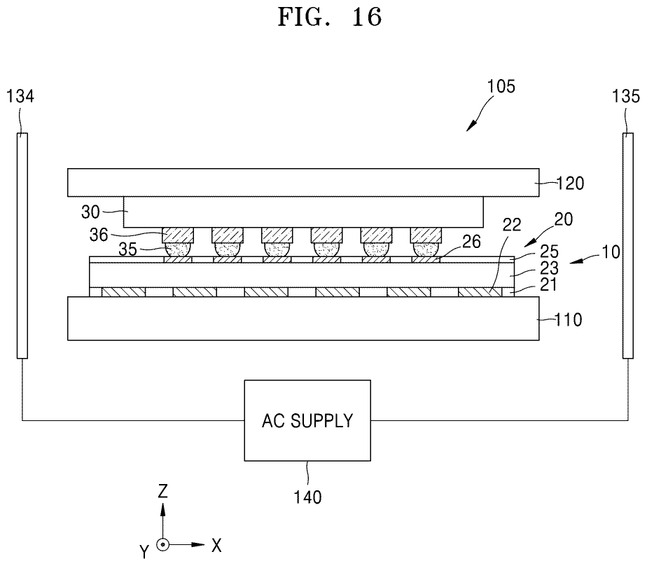

Referring to FIG. 16, the apparatus 105 for manufacturing a semiconductor package may include the first side induction coil 134 and a second side induction coil 135, each arranged on a side of the semiconductor chip 30. For example, in an embodiment, the first side induction coil 134 may be arranged on a lateral side of the semiconductor chip 30 in the −X direction and the second side induction coil 135 may be arranged on a lateral side of the semiconductor chip 30 in the X direction. However, embodiments of the present inventive concept are not necessarily limited thereto. The first side induction coil 134 and the second side induction coil 135 may be arranged on sides (e.g., lateral ends) of the support plate 110, the substrate 20, the semiconductor chip 30, and the pick-up tool 120. For example, the first side induction coil 134 and the second side induction coil 135 may overlap the semiconductor chip 30 in the first horizontal direction (the X direction and the −X direction). The first side induction coil 134 and the second side induction coil 135 may be spaced apart from each other in the first horizontal direction (the X direction) with the semiconductor chip 30 therebetween. In some embodiments, the first side induction coil 134 and the second side induction coil 135 may overlap the support plate 110, the substrate 20, the semiconductor chip 30, and/or the pick-up tool 120 in the first horizontal direction (the X direction and the −X direction).

In some embodiments, the first side induction coil 134 and the second side induction coil 135 may overlap the semiconductor chip 30 in the second horizontal direction (e.g., the Y direction and the −Y direction). The first side induction coil 134 and the second side induction coil 135 may overlap the support plate 110, the substrate 20, the semiconductor chip 30, and/or the pick-up tool 120 in the second horizontal direction (e.g., the Y direction and the −Y direction). In some embodiments, the first side induction coil 134 and the second side induction coil 135 may be spaced apart from each other in the second horizontal direction (e.g., the Y direction) with the semiconductor chip 30 therebetween.

As described with reference to FIGS. 1 to 9, the AC supply 140 may supply AC power to the first side induction coil 134 and the second side induction coil 135. As a result, self-resistance heat may be generated in the conductive solder 35. Due to the self-resistance heat, the conductive solder 35 may be bonded to the substrate 20. Due to the self-resistance heat, the semiconductor chip 30 may be bonded to the substrate 20.

While the present inventive concept has been particularly shown and described with reference to non-limiting embodiments thereof, it will be understood that various changes in form and details may be made therein without departing from the spirit and scope of the present inventive concept.

What is claimed is:

1. A method of manufacturing a semiconductor package, the method comprising:
providing a substrate on a support plate;
placing a semiconductor chip on the substrate by a pick-up tool; and
supplying an alternating current voltage to an induction coil positioned adjacent to the semiconductor chip,
wherein the pick-up tool comprises an insulating material.

2. The method of claim 1, wherein:
the placing of the semiconductor chip on the substrate comprises placing a conductive solder disposed under the semiconductor chip on the substrate: and
the induction coil is arranged adjacent to the conductive solder.

3. The method of claim 2, wherein the substrate comprises:
a wiring layer;
an upper insulating layer on the wiring layer; and
a pad surrounded by the upper insulating layer, the pad directly contacting the conductive solder.

4. The method of claim 1, wherein the providing of the substrate on the support plate comprises adsorbing the substrate to the support plate.

5. The method of claim 4, wherein the adsorbing of the substrate to the support plate comprises applying negative pressure to a space between the support plate and the substrate.

6. The method of claim 1, further comprising applying pressure to the semiconductor chip in a direction towards the substrate by the pick-up tool.

7. The method of claim 1, wherein the pick-up tool does not comprise a heater.

8. The method of claim 1, wherein the method does not comprise heating the pick- up tool by using a separate heater.

9. The method of claim 1, wherein the semiconductor chip and the substrate are bonded together by a conductive solder disposed under the semiconductor chip.

10. The method of claim 1, further comprising applying self-resistance heat to a conductive solder disposed under the semiconductor chip.

11. A method of manufacturing a semiconductor package, the method comprising:
providing a substrate on a support plate;
placing a semiconductor chip and a conductive solder disposed under the semiconductor chip on the substrate by a pick-up tool;
supplying an alternating current voltage to an induction coil positioned adjacent to the conductive solder; and
applying heat to the conductive solder by the alternating current voltage of the induction coil.

12. The method of claim 11, further comprising the conductive solder bonding the semiconductor chip and the substrate together when the heat is applied to the conductive solder.

13. The method of claim 11, wherein the pick-up tool comprises an insulating material.

14. The method of claim 11, wherein the heat applied to the conductive solder is caused by an eddy current generated due to the alternating current voltage.

15. The method of claim 14, wherein the heat applied to the conductive solder is self-resistance heat due to the eddy current.

16. An apparatus for manufacturing a semiconductor package, the apparatus comprising:
a support plate supporting a substrate;
a pick-up tool placing a semiconductor chip on the substrate, the semiconductor chip including a conductive solder disposed under the semiconductor chip and positioned between the semiconductor chip and the substrate;
an induction coil positioned adjacent to the semiconductor chip; and
an alternating current supply supplying an alternating current voltage to the induction coil,
wherein, when the alternating current voltage is supplied to the induction coil, heat is applied to the conductive solder to bond the substrate and the semiconductor chip together.

17. The apparatus of claim 16, wherein the support plate absorbs and fixes the substrate.

18. The apparatus of claim 16, wherein the pick-up tool comprises an insulating material, does not comprise a heater, and is not heated by a separate heater.

19. The apparatus of claim 16, wherein, when the alternating current voltage is supplied to the induction coil, an eddy current is generated in the conductive solder.

20. The apparatus of claim 19, wherein the heat applied to the conductive solder is self-resistance heat due to the eddy current.
